(19) United States
(12) Patent Application Publication
(10) Pub. No.: US 2025/0043408 A1
(43) Pub. Date: Feb. 6, 2025

(54) STACKABLE MASK

(71) Applicant: Samsung Display Co., LTD., Yongin-si (KR)

(72) Inventors: SUNGMIN YUN, Yongin-si (KR); SUNTAEK HONG, Yongin-si (KR); JAE IK BAE, Yongin-si (KR); HEUNGWON LEE, Yongin-si (KR)

(73) Assignee: Samsung Display Co., LTD., Yongin-si (KR)

(21) Appl. No.: 18/767,138

(22) Filed: Jul. 9, 2024

(30) Foreign Application Priority Data
Aug. 2, 2023 (KR) 10-2023-0100894

(51) Int. Cl. C23C 14/04; H10K 71/16

(52) U.S. Cl. CPC C23C 14/042; H10K 71/166

(57) ABSTRACT

A method of loading a plurality of stackable masks for depositing organic light emitting diodes (OLEDs) includes loading an upper stackable mask on a stacking guide of a lower stackable mask, wherein each of the stackable masks includes a mask body having a rectangle shape; and the stacking guide disposed at a central portion of each of four side edges of the mask body.

### CROSS-REFERENCE TO RELATED APPLICATION

This application claims priority to and the benefit of Korean Patent Application No. 10-2023-0100894 under 35 U.S.C. § 119, filed in the Korean Intellectual Property Office (KIPO) on Aug. 2, 2023, the entire contents of which are incorporated herein by reference.

### BACKGROUND

### 1. Technical Field

The disclosure relates to a mask, and more specifically, to a stackable mask that can be loaded without a separate mask cassette.

### 2. Description of the Related Art

In general, when masks are supplied to a facility for depositing organic light emitting diodes (OLEDs), a unit of masks is loaded onto a mask cassette. Specifically, about five masks are loaded onto the mask cassette.

Korean Patent No. 10-1802863 discloses a mask cassette.

The mask cassette disclosed in Korean Patent No. 10-1802863 includes a slot into which a mask is loaded; an upper frame covering an upper side of the slot; a lower frame provided on a lower side of the slot; a side frame extending in a vertical direction, connected between the upper frame and the lower frame, and supporting the slot; and a pad coupled to an upper surface of the slot to contact the mask, and made of a material having a larger strength than the slot.

In addition, Korean Patent Application Publication No. 10-2017-0132068 discloses a deposition mask.

The deposition mask disclosed in Korean Patent Application Publication No. 10-2017-0132068 is a deposition mask in such a type that a mask body is supported by a frame body to be realized in a big size while suppressing an increase in manufacturing cost and maintaining its flatness, thereby making it possible to ensure good precision in reproducibility and deposition.

However, in order to move such a mask to a deposition facility, a mask cassette is required. Accordingly, separate components such as facilities for storing the mask cassette and the mask, respectively, have been conventionally required.

Conventionally, since two types of items, for example, a mask and a mask cassette, are conveyed, it is required to establish facilities for conveying the mask and the mask cassette, respectively, resulting in a disadvantage in that logistics investment cost and logistics load are high.

As a relevant art, Korean Patent No. 10-1641087 discloses a pallet for transporting a large-size display panel for an electronic device. Korean Patent No. 10-1641087 relates to a pallet for transporting a large-size display panel for an electronic device capable of stably supporting upper and side surfaces of a panel for a large-size electronic device, securing stable mobility by pressurizing the upper surface of the panel when transporting pallets are stacked, and absorbing an impact caused between transporting pallets when stacked. The pallet includes a lower frame formed by arranging a plurality of first and second support frames on upper and lower sides, respectively, with a plurality of reinforcing bars integrally formed therebetween; an upper frame formed by arranging a plurality of support bars on an upper surface of the lower frame and coupling horizontal bars and vertical bars to each other on the plurality of support bars; a shock absorbing pad for absorbing and buffering shock according to the load of panels stacked on an upper surface of the upper frame and shaking during transportation; inter-pallet stacking protrusions and locking grooves formed at corresponding upper and lower ends of respective edges of the lower frame so that the pallets can be effectively interlocked with each other when the pallets are stacked in a vertical direction; side support units provided on four external sides of the lower frame to prevent panels seated and stacked in multiple stages on the shock absorbing pad from escaping in a lateral direction; and horizontal support units provided in a section corresponding to a surface of an uppermost one among the panels seated on the front and rear sides of the upper surface of the lower frame and stacked in multiple stages on the upper surface of the lower frame to fundamentally limit the shaking of the panels stacked in multiple stages.

Although Korean Patent No. 10-1641087 discloses a configuration in which stacking protrusions and locking grooves are formed on a plurality of pallets in order to stack the pallets vertically, there is a problem in that no clamp is allowed to enter between the pallets.

As a relevant art, Korean Patent No. 10-2445717 discloses a mask, a mask loading module on which a mask is loaded, and a substrate processing system including the mask loading module.

Korean Patent No. 10-2445717 discloses a mask loading module including a mask frame with a plurality of grooves formed in a bottom surface thereof to load a mask for use in processing a substrate, the mask loading module including a plurality of pins installed at positions corresponding to the plurality of grooves, respectively, and inserted into the respective grooves to support a lower surface of the mask frame; and a pin installation part in which the plurality of pins are installed so that the mask frame is put on and supported by the plurality of pins, wherein the plurality of pins include at least two alignment pins corresponding to at least two alignment grooves each having an inclined portion inside to align a horizontal position of the mask frame, among the plurality of grooves, and inserted into the at least two alignment grooves due to the weight of the mask.

Although Korean Patent No. 10-2445717 discloses a configuration of the pin installation part formed in the mask loading module to load a mask, Korean Patent No. 10-2445717 does not disclose a configuration in which seating guides for omitting a cassette are formed on a mask in order to improve a flow of logistics and reduce a weight of a facility.

### SUMMARY

The disclosure provides a stackable mask that can be stacked without a mask cassette.

An embodiment of the disclosure provides a stackable mask including:
a mask body having a rectangle shape; and
a stacking guide disposed at a central portion of each of four side edges of the mask body.

The stacking guide may be disposed higher than the mask body by a height to load another stackable mask on the stacking guide.

The stacking guide may have a guide surface that guides another stackable mask to be loaded onto the stacking guide.

The guide surface may have an inclination in a range of about 30 degrees to about 60 degrees with respect to the stacking guide.

In case that the stackable mask is stacked on another stackable mask, the stackable mask may be loaded on a stacking guide of the another stackable mask.

Transferring and loading entrances may be disposed on sides of the stacking guide to allow a clamp to enter between the stacked stackable masks, and the transferring and loading entrances may be empty spaces.

In case that the stackable masks is stacked on the another stackable mask, the stacking guide of the stackable mask and the stacking guide of the another stackable mask may be vertically aligned to apply a load to the stacking guide of the another stackable mask.

A side surface of the stacking guide of another stackable mask may fix the stackable mask loaded on the stacking guide of the another stackable mask.

A height difference may be formed between the stacking guide and a lower end of the guide surface as much as a height of the side surface.

The guide surface may include a material that is capable of suppressing generation of static electricity.

An inclined surface of the guide surface may have a length in a range of about 10 mm to about 20 mm.

A length, a width, and a height of the mask body may be about 1701 mm, about 1067 mm, and about 35 mm, respectively.

Another embodiment of the disclosure provides a method of loading a plurality of stackable masks for depositing organic light emitting diodes (OLEDs), the method including loading an upper stackable mask on a stacking guide of a lower stackable mask, wherein each of the stackable masks includes a mask body having a rectangle shape; and a stacking guide disposed at a central portion of each of four side edges of the mask body.

Transferring and loading entrances may be disposed on sides of the stacking guide to allow a clamp to enter between the stacked stackable masks, and the transferring and loading entrances are empty spaces.

In case that the plurality of stackable masks are stacked, stacking guides of stacked stackable masks may be vertically aligned with an upper or lower stacking guide to apply a load to the stacking guides.

The stacking guide may be disposed higher than the mask body by a height to load another stackable mask on the stacking guide.

The stacking guide may have a guide surface that guides another stackable mask to be loaded onto the stacking guide.

The guide surface may have an inclination in a range of about of 30 degrees to about 60 degrees with respect to the stacking guide.

A side surface of the stacking guide may fix the upper stackable mask loaded on the stacking guide.

A height difference may be formed between the stacking guide and a lower end of the guide surface as much as a height of the side surface.

According to the embodiments, the number of types of conveyed items can be reduced by improving the mask loading method, and the investment cost can be reduced and the mask supply flow performed by the facility for the deposition process can be improved through a single configuration of a storage facility.

### BRIEF DESCRIPTION OF THE DRAWINGS

FIG. 1 is a schematic view showing a stackable mask according to an embodiment.

FIG. 2 is a schematic side view showing a stackable mask according to an embodiment.

FIG. 3 is a schematic view showing a stacking guide of a stackable mask according to an embodiment.

FIG. 4 is a schematic view showing a state in which stackable masks are stacked according to an embodiment.

FIG. 5 is a schematic side view showing a state in which stackable masks are stacked according to an embodiment.

FIG. 6 is a schematic side view illustrating transferring and loading entrances in a state in which stackable masks are stacked according to an embodiment.

### DETAILED DESCRIPTION OF THE EMBODIMENTS

Hereinafter, several embodiments of the disclosure will be described in detail with reference to the accompanying drawings so that they can be readily carried out by those of ordinary skill in the art to which the disclosure pertains. The disclosure may be implemented in many different forms, and is not limited to the embodiments described herein.

In order to clearly describe the disclosure, parts repetitive or irrelevant to the description may be omitted, and the same or similar components will be denoted by the same reference signs throughout the specification.

The size and thickness of each component shown in the drawings may be arbitrary for convenience of description, and the disclosure is not necessarily limited to what is illustrated. In the drawings, thicknesses of several layers and regions are enlarged for clarity. In addition, in the drawings, for convenience of explanation, thicknesses of some layers and regions may be exaggerated.

When a part such as a layer, a film, a region, a plate, or a component is referred to as being “on” another part, it may be “directly on” the another part or there may be an intervening part therebetween. In contrast, when a part is referred to as being “directly on” another part, there is no intervening part therebetween. In addition, when a part is referred to as being “on” a reference part, it is located on or under the reference part, and does not necessarily mean that it is located “on” the reference part in the opposite direction of gravity.

Throughout the specification, when a certain part is referred to as “including,” “comprising,” or “having” a certain component, this implies the presence of other components, not precluding the presence of other components, unless explicitly stated to the contrary.

Throughout the specification, the phrase “in a plan view” means when a target part is viewed from above, and the phrase “in a cross-sectional view” means when a cross section of a target part as vertically cut is viewed laterally.

When an element is referred to as being “connected to,” or “coupled to” another element, it may be directly connected to, or coupled to the other element or intervening elements or layers may be present. When, however, an element is referred to as being “directly connected to,” or “directly coupled to” another element, there are no intervening elements or layers present. To this end, the term “connected” may refer to physical, electrical, and/or fluid connection, with or without intervening elements.

Throughout the specification, when a part such as a wire, a layer, a film, a region, a plate, or a component is referred to as “extending in a first direction or in a second direction”, this means not only a straight-line shape of the part running straight in the first direction or the second direction, but also a structure of the part generally extending in the first direction or in the second direction, including a partially bent structure, a zigzag-shaped structure, or a curved structure.

An electronic device (e.g., a mobile phone, a TV, a monitor, or a laptop computer) including a display device, a display panel, or the like as described in the specification, and an electronic device including a display device, a display panel, or the like as manufactured according to a manufacturing method described in the specification are not excluded from the scope of the specification.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

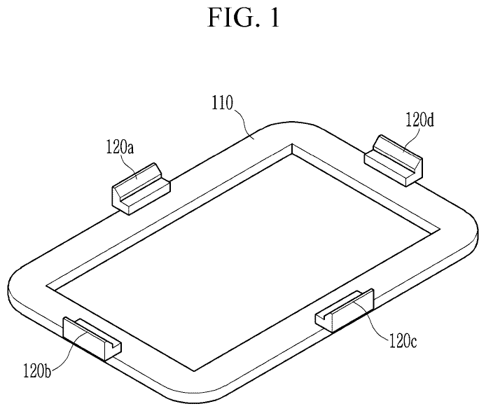

Hereinafter, a stackable mask according to an embodiment will be described with reference to FIGS. 1 to 3.

FIG. 1 is a schematic view showing a stackable mask according to an embodiment.

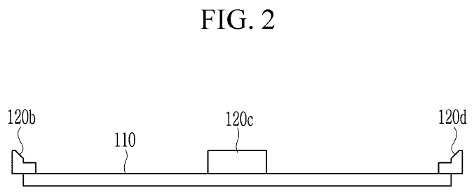

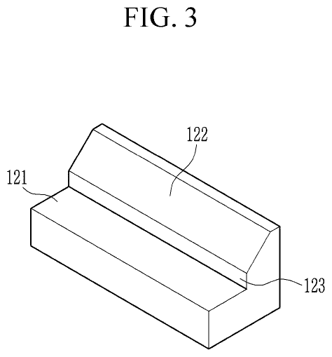

FIG. 2 is a schematic side view showing a stackable mask according to an embodiment. FIG. 3 is a schematic view showing a stacking guide of a stackable mask according to an embodiment.

Referring to FIGS. 1 to 3, a stackable mask according to an embodiment may include a mask body 110 and stacking guides 120a, 120b, 120c, and 120d.

The mask body 110 may be formed in a rectangle shape, and may be cut out in a rectangle shape to form a large hole inside.

The mask body 110 may have a length in a range of about 1701 mm, a width in a range of about 1067 mm, and a height in a range of about 35 mm, which are similar to those in a mask according to the related art.

Referring to FIG. 1 or 2, the stacking guides 120a, 120b, 120c, and 120d may be formed at respective central portions of four side edges of the mask body 110. If desired, the stacking guides 120a, 120b, 120c, and 120d may be formed in areas other than the central portions of the four side edges of the mask body 110, or may be formed in the central portions of the four side edges of the mask body 110 in terms of weight distribution.

The number of the stacking guides 120a, 120b, 120c, and 120d may be modified if desired. For example, if the length of the mask body 110 increases, stacking guides may be added on sides (e.g., both sides) or at other portions of the mask body 110.

However, even if the number of stacking guides 120a, 120b, 120c, and 120d or the sizes of the stacking guides 120a, 120b, 120c, and 120d are modified, it may be required that a clamp of a transferring and loading facility be able to enter between the stackable masks in a stacked state. For example, it may be required that transferring and loading entrances 130, which are empty spaces, be formed on sides (e.g., both sides) of the stacking guides 120a, 120b, 120c, and 120d.

Therefore, the number of stacking guides 120a, 120b, 120c, and 120d, the sizes of the stacking guides 120a, 120b, 120c, and 120d, or the positions of the stacking guides 120a, 120b, 120c, and 120d may be modified within the range in which the clamp of the transferring and loading facility is able to enter between the stackable masks.

Referring to FIG. 3, each of the stacking guides 120a, 120b, 120c, and 120d may have a stacking guide 121 formed higher than the mask body 110 by a height (e.g., a predetermined or selectable height) to load another stackable mask thereon. For example, a step (or height difference) in a range of about 30 mm to about 50 mm may be formed between the stacking guide 121 and the mask body 110.

The transferring and loading entrances 130, which are empty spaces, may be formed by such a step, and thus, the height difference may also be modified within a range in which the clamp of the transferring and loading facility is able to enter between the stackable masks.

The height of the transferring and loading entrance 130, which is an empty space, may increase as the height difference increases, whereas the length of the transferring and loading entrance 130 may decrease as the length of each of the stacking guides 120a, 120b, 120c, and 120d increases.

For example, the height difference may be equal to the height of the transferring and loading entrance 130, which is an empty space, and the length of the mask body 110 may correspond to the sum of the length of each of the stacking guides 120a, 120b, 120c, and 120d and twice the length of the transferring and loading entrance 130.

Referring to FIG. 3, each of the stacking guides 120a, 120b, 120c, and 120d may have a guide surface 122 formed to guide another stackable mask to be loaded onto the stacking guide 121.

A side surface 123 of the stacking guide 121 may serve to fix the upper stackable mask loaded on the stacking guide 121 so that the upper stackable mask does not move. As a result, a lower surface of the mask body 110 loaded on the stacking guide 121 may be in contact with the stacking guide 121, and four side surfaces of the mask body 110 may be in contact with the side surfaces 123 of the stacking guides 120a, 120b, 120c, and 120d, respectively, thereby correctly fixing the mask body 110.

Referring to FIG. 3, a step (or height difference) may be formed between the stacking guide 121 and a lower end of the guide surface 122 as much as the height of the side surface 123.

An inclined surface of the guide surface 122 may have a length in a range of about 10 mm to about 20 mm. The length of the inclined surface of the guide surface 122 may be modified, if desired, e.g., depending on an angle of inclination.

Each of the stacking guides 120a, 120b, 120c, and 120d may have a height in a range of about 60 mm to about 80 mm, a width in a range of about 80 mm to about 120 mm, and a length in a range of about 100 mm to about 160 mm. These numerical values may correspond to the mask body, and may be examples in a case where the length, the width, and the height of the mask body 110 are about 1701 mm, about 1067 mm, and about 35 mm, respectively. Therefore, if the length, the width, and the height of the mask body 110 are modified, the length of the inclined surface may be modified.

The height difference between the mask body 110 and the stacking guide 121 may be in a range of about 30 mm to about 50 mm or may be about 40 mm.

The height of the side surface 123 may be in a range of about 3 to about 7 mm or may be about 5 mm.

A width of an upper extension surface of the guide surface 122 may be in a range of about 3 mm to about 7 mm or may be about 5 mm.

The guide surface 122 may have an inclination in a range of about 30 degrees to about 60 degrees with respect to the stacking guide.

The numerical values of the height difference between the mask body 110 and the stacking guide 121, the height of the side surface 123, and the width of the upper extension surface of the guide surface 122 may correspond to the mask body 110, and may be examples in a case where the length, the width, and the height of the mask body 110 are about 1701 mm, about 1067 mm, and about 35 mm, respectively. Therefore, if the length, the width, and the height of the mask body 110 are modified, the length of the inclined surface may be modified.

These numerical limitations of the stacking guides 120a, 120b, 120c, and 120d are merely examples, and may be modified if desired.

The length, the width, and the height of the mask body 110 may be about 1701 mm, about 1067 mm, and about 35 mm, respectively, and these numerical values may also be modified.

The stacking guides 120a, 120b, 120c, and 120d may be manufactured of a single material or a synthetic material that is light but strong, such as metal, resin, or plastic, and the material of the stacking guides 120a, 120b, 120c, and 120d may be modified in various manners if desired.

The guide surface 122 may guide a mask body 110 of another stackable mask onto the stacking guide 121 correctly in case that another stackable mask is loaded from above the guide surface 122. The guide surface 122 is a portion with which the mask body 110 is to be brought into contact, and may be understood as a member guiding the mask body 110 by introducing a guide slope of a certain angle (for example, in the range of about 30 degrees to about 60 degrees) in the portion with which the mask body 110 is to be brought into contact so that the mask body 110 is seated on the stacking guide 121 after sliding along the guide slope.

The guide surface 122 and the side surface 123 may be understood as members serving as guard support rods that may prevent the mask body from escaping from the stacking guide 121.

If desired, the guide surface 122 may include a material that is capable of suppressing generation of static electricity, such as Teflon™, to suppress adhesion or adsorption of impurities or foreign substances caused by static electricity in case that the mask body is in contact with the guide surface 122.

In case that the stackable masks are stacked, the upper stackable mask may be loaded on the stacking guides 120a, 120b, 120c, and 120d of the lower stackable mask.

Transferring and loading entrances 130, which are empty spaces, may be formed on sides (e.g., both sides) of the stacking guides 120a, 120b, 120c, and 120d to allow a clamp to enter between the stacked stackable masks.

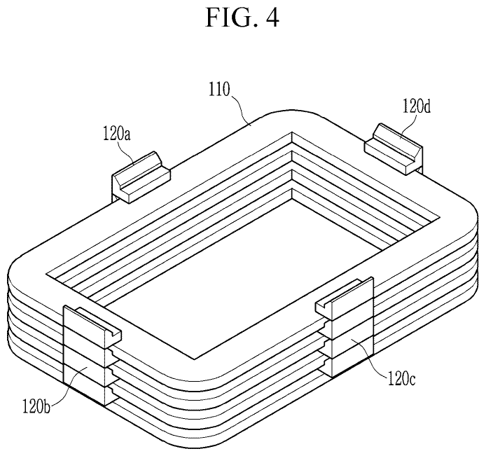

Hereinafter, a method of loading stackable masks according to an embodiment will be described with reference to FIGS. 4 to 6.

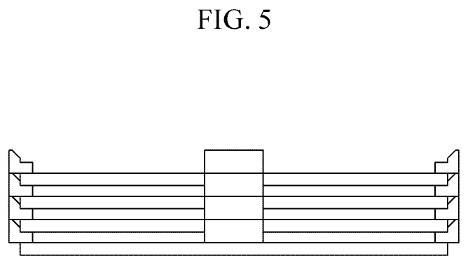

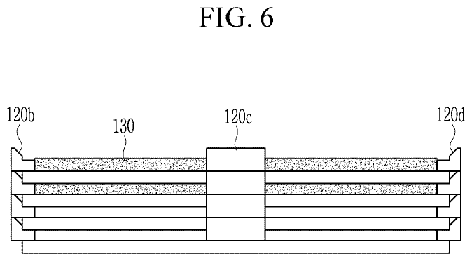

FIG. 4 is a schematic view showing a state in which stackable masks are stacked according to an embodiment. FIG. 5 is a schematic side view showing a state in which stackable masks are stacked according to an embodiment. FIG. 6 is a schematic side view illustrating transferring and loading entrances in a state in which stackable masks are stacked according to an embodiment.

Referring to FIGS. 4 and 5, in a method of loading stackable masks for depositing organic light emitting diodes (OLEDs), first, a stackable mask may be loaded on another stackable mask.

Then, the mask body 110 of the upper stackable mask may be guided along the inclined guide surfaces 122 of the stacking guides 120a, 120b, 120c, and 120d of the lower stackable mask, and seated on the stacking guides 121. In an embodiment, the guide surfaces 122 may be inclined inward from the outside, and the mask body 110 may be guided inward along the inclined guide surfaces 122 of the stacking guides 120a, 120b, 120c, and 120d of the lower stackable mask, and seated on the stacking guides 121. For example, even if some of the four corners of the mask body 110 of the upper stackable mask are initially placed on the inclined surfaces 122 in a slightly deviated state, not at correct positions, the mask body 110 may be seated on the stacking guides 121 after being guided along the inclined guide surfaces 122 of the stacking guides 120a, 120b, 120c, and 120d of the lower stackable mask.

Here, the guide surfaces 122 may include a material that is capable of suppressing generation of static electricity, such as Teflon™, to suppress adhesion or adsorption of impurities or foreign substances caused by static electricity in case that the mask body 110 is in contact with the guide surfaces 122.

In a state where the upper stackable mask is seated on the lower stackable mask, the side surfaces 123 of the stacking guides 120a, 120b, 120c, and 120d of the lower stackable mask may serve to prevent the mask body 110 from escaping from the stacking guides 121 and fix the mask body 110.

Next, another stackable mask may be loaded on the two stackable masks.

Then, a mask body 110 of another upper stackable mask may be guided along the guide surfaces 122 of the stacking guides 120a, 120b, 120c, and 120d of the lower stackable mask, and seated on the stacking guides 121. In this case, the guide surfaces 122 may include a material that is capable of suppressing generation of static electricity, such as Teflon™, to suppress adhesion or adsorption of impurities or foreign substances caused by static electricity in case that the mask body 110 is in contact with the guide surfaces 122. For example, the guide surfaces 122 may be inclined inward from the outside, and the mask body 110 may be guided inward along the inclined guide surfaces 122 of the stacking guides 120a, 120b, 120c, and 120d of the lower stackable mask, and seated on the stacking guides 121.

In a state where the another upper stackable mask is seated on the lower stackable mask, the side surfaces 123 of the stacking guides 120a, 120b, 120c, and 120d of the lower stackable mask may serve to prevent the mask body 110 from escaping from the stacking guides 121 and fix the mask body 110.

Afterwards, other stackable masks may be sequentially loaded in the same way, and in an embodiment, five stackable masks may be loaded in total.

This structure is a structure in which there is no variation in loaded form between the stackable masks when seated and piled up in a stacked manner. In particular, in case that stackable masks are stacked, the stacking guides 120a, 120b, 120c, and 120d of the stacked stackable masks may be vertically aligned with the upper or lower stacking guides 120a, 120b, 120c, and 120d to apply a load thereto.

In case that stackable masks are stacked, the stacking guides 120a, 120b, 120c, and 120d of the stacked stackable masks may not be vertically aligned with upper or lower stacking guides 120a, 120b, 120c, and 120d, but this may be disadvantageous in supporting the load.

If there is no problem in supporting the weight of the mask body, the stacking guides 120a, 120b, 120c, and 120d of the stacked stackable masks may not be vertically aligned with upper or lower stacking guides 120a, 120b, 120c, and 120d. For example, in a case where the number of stacking guides 120a, 120b, 120c, and 120d or the sizes of the stacking guides 120a, 120b, 120c, and 120d increase, the stacking guides 120a, 120b, 120c, and 120d of the stacked stackable masks may not be vertically aligned with upper or lower stacking guides 120a, 120b, 120c, and 120d. Therefore, in case that stackable masks are stacked, it may be advantageous that the stacking guides 120a, 120b, 120c, and 120d of the stacked stackable masks are vertically aligned with upper or lower stacking guides 120a, 120b, 120c, and 120d to apply a load.

The guide surface 122 for each of the stacking guides 120a, 120b, 120c, and 120d may have an inclination in a range of about 30 degrees to about 60 degrees with respect to the stacking guide, and another stackable mask may be guided to be loaded onto the stacking guide 121 in case that a mask body 110 of another stackable mask is loaded on the stacking guides 120a, 120b, 120c, and 120d.

This is a structure that may help the mask body 110 of another upper stackable mask to be seated through the guide surfaces 122 in case that the masks are stacked, and is a structure that may be capable of additionally supplementing transferring and loading precision.

If desired, the angle and the shape of the guide surface 122 may be modified.

As shown in FIG. 6, transferring and loading entrances 130, which are empty spaces, may be formed on sides (e.g., both sides) of the stacking guides 120a, 120b, 120c, and 120d to allow a clamp to enter between the stacked stackable masks.

Therefore, the structure using the transferring and loading entrances 130 to transfer and load the stackable masks allows a clamp to enter between side surfaces of the stacked stackable masks so that the transferring and loading facility may transfer and load the mask. Here, the position of the transferring and loading structure using the transferring and loading entrances 130, which are gaps between the side surfaces of the stacked stackable masks, may be modified. Here, the transferring and loading facility and the clamp may be a facility and a device known in the related art, and thus, detailed descriptions thereof will be omitted.

If desired, the stack type structure may be modified to an assembly type structure.

For example, stack type guides may be assembled with each other, and in this case, it may be required to form transferring and loading entrances so that a clamp is allowed to enter between masks.

As an assembly method, a known assembly method may be applied, or an assembly method modified to be suitable for the masks may be applied.

If desired, the stack type structure may be modified to a module type structure.

For example, stack type guides may be combined with each other in a modular manner, and in this case, it may be required to form transferring and loading entrances so that a clamp is allowed to enter between masks.

As a modular method, a known modular method may be applied, or a modular method modified to be suitable for the masks may be applied.

If desired, the mask body and the stacking guides may be combined with each other in an assembly type or in a modular manner.

Accordingly, grooves or projections may be formed on the mask body, and projections or grooves may also be formed on the stacking guides.

In the conventional loading method, two types of conveyed items, that is, a mask cassette and a mask, were used, and respective logistics facilities were individually configured for the mask cassette and the mask. Accordingly, maintenance costs were high. In contrast, according to the disclosure, only one type of conveyed item, that is, masks, needs to be maintained and managed. As a result, maintenance and management are convenient and cost can be reduced.

In the conventional loading method, after masks were sequentially loaded from an upper end to a lower end of the mask cassette, the masks were moved to a facility for a deposition process in a state where the masks are loaded on the mask cassette. In this case, the mask cassette weighed about 600 kg in case that five masks were fully loaded on the mask cassette, and the mask cassette weighed about 210 kg in case that the mask cassette was empty.

According to the disclosure, as compared thereto, since no mask cassette is required, and each mask weighs about 90 kg, the total weight of masks when loaded in five stages may be about 450 kg, which is about 150 kg lighter than the total weight in the conventional art.

In the conventional art, a mask cassette was taken out from a mask cassette storage facility, the mask cassette was placed in a fixed port using a transferring and loading facility, and then the mask cassette was discharged through a mask cassette transport facility. In contrast, according to the disclosure, since no mask cassette is required, the procedure related to a mask cassette storage facility is not required. As a result, the work process is greatly shortened, and the time for transferring and loading work is shortened.

Conventionally, a procedure for a mask storage facility to place the mask cassette in the fixed port through the mask cassette transport facility was required. In contrast, according to the disclosure, this procedure is not necessary because no mask cassette is required. As a result, the work time and work cost related to the mask storage facility can be reduced.

The subsequent work performed by a facility for the deposition process according to the disclosure may be similar to the subsequent work performed by a conventional facility for the deposition process. For example, the stackable mask may be placed in the transferring and loading facility and put into the facility for the deposition process.

As described above, according to the disclosure, the number of types of conveyed items may be reduced by improving the loading method, and the investment cost may be reduced and the mask supply flow performed by the facility for the deposition process may be improved through a single configuration of a storage facility. In particular, according to the disclosure, a mask cassette used to load masks may be omitted, and the reductions in working time and cost can be improved.

The above description is an example of technical features of the disclosure, and those skilled in the art to which the disclosure pertains will be able to make various modifications and variations. Thus, the embodiments of the disclosure described above may be implemented separately or in combination with each other.

The embodiments disclosed in the disclosure are intended not to limit the technical spirit of the disclosure but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A stackable mask comprising:
a mask body having a rectangle shape; and
a stacking guide disposed at a central portion of each of four side edges of the mask body.

2. The stackable mask of claim 1, wherein the stacking guide is disposed higher than the mask body by a height to load another stackable mask on the stacking guide.

3. The stackable mask of claim 2, wherein the stacking guide has a guide surface that guides another stackable mask to be loaded onto the stacking guide.

4. The stackable mask of claim 3, wherein the guide surface has an inclination in a range of about 30 degrees to about 60 degrees with respect to the stacking guide.

5. The stackable mask of claim 4, wherein in case that the stackable mask is stacked on another stackable mask, the stackable mask is loaded on a stacking guide of the another stackable mask.

6. The stackable mask of claim 5, wherein
transferring and loading entrances are disposed on sides of the stacking guide to allow a clamp to enter between the stacked stackable masks, and
the transferring and loading entrances are empty spaces.

7. The stackable mask of claim 6, wherein in case that the stackable mask is stacked on the another stackable mask, the stacking guide of the stackable mask and the stacking guide of the another stackable mask are vertically aligned to apply a load to the stacking guide of the another stackable mask.

8. The stackable mask of claim 7, wherein a side surface of the stacking guide of another stackable mask fixes the stackable mask loaded on the stacking guide of the another stackable mask.

9. The stackable mask of claim 8, wherein a height difference is formed between the stacking guide and a lower end of the guide surface as much as a height of the side surface.

10. The stackable mask of claim 3, wherein the guide surface includes a material that is capable of suppressing generation of static electricity.

11. The stackable mask of claim 10, wherein an inclined surface of the guide surface has a length in a range of about 10 mm to about 20 mm.

12. The stackable mask of claim 1, wherein a length, a width, and a height of the mask body are about 1701 mm, about 1067 mm, and about 35 mm, respectively.

13. A method of loading a plurality of stackable masks for depositing organic light emitting diodes (OLEDs), comprising:
loading an upper stackable mask on a stacking guide of a lower stackable mask,
wherein each of the stackable masks includes:
a mask body having a rectangle shape; and
the stacking guide disposed at a central portion of each of four side edges of the mask body.

14. The method of claim 13, wherein
transferring and loading entrances are disposed on sides of the stacking guide to allow a clamp to enter between the stacked stackable masks, and
the transferring and loading entrances are empty spaces.

15. The method of claim 14, wherein in case that the plurality of stackable masks are stacked, stacking guides of the stacked stackable masks are vertically aligned with an upper or lower stacking guide to apply a load to the stacking guides.

16. The method of claim 15, wherein the stacking guide is disposed higher than the mask body by a height to load another stackable mask on the stacking guide.

17. The method of claim 16, wherein the stacking guide has a guide surface that guides another stackable mask to be loaded onto the stacking guide.

18. The method of claim 17, wherein the guide surface has an inclination in a range of about 30 degrees to about 60 degrees with respect to the stacking guide.

19. The method of claim 18, wherein a side surface of the stacking guide fixes the upper stackable mask loaded on the stacking guide.

20. The method of claim 19, wherein a height difference is formed between the stacking guide and a lower end of the guide surface as much as a height of the side surface.
